(19) United States
(12) Patent Application Publication
(10) Pub. No.: US 2026/0309783 A1
(43) Pub. Date: Oct. 8, 2026

(54) ENERGY STORAGE CAPACITY ESTIMATION IN AEROSOL-GENERATING SYSTEMS

(71) Applicant: Philip Morris Products S.A., Neuchatel (CH)

(72) Inventors: Levon ASLANYAN, Yerevan (AM); Camille Valery GROSJEAN, Renens (CH); Monika SEKOYAN, Yerevan (AM); Olivier TROISFONTAINE, Neuchâtel (CH)

(73) Assignee: Philip Morris Products S.A., Neuchatel (CH)

(21) Appl. No.: 19/482,416

(22) PCT Filed: Apr. 25, 2024
(86) PCT No.: PCT/EP2024/061450

§ 371 Date: Nov. 7, 2025

(30) Foreign Application Priority Data
May 12, 2023 (AM) AM20230047

(51) Int. Cl. G01R 31/367; A24F 40/53; A24F 40/60; A24F 40/65; G01R 31/371; G01R 31/392; H02J 7/84

(52) U.S. Cl. CPC G01R 31/367; A24F 40/53; A24F 40/60; A24F 40/65; G01R 31/371; G01R 31/392; H02J 7/84

(57) ABSTRACT

A computer-implemented method for estimating a capacity of an energy storage of an aerosol-generating device or a companion device configured to charge an aerosol-generating device with electrical energy is provided, the method including: collecting charging profile data of the energy storage, the charging profile data including a charging profile, selecting, in the charging profile data, a data segment of the charging profile, the data segment of the charging profile being selected so that the data segment lies next to a corner point of the charging profile; and determining an estimated capacity of the energy storage from the data segment of the charging profile.

The present disclosure relates to a computer-implemented method for estimating a capacity of an energy storage of an aerosol-generating device or a companion device configured to charge an aerosol-generating device with electrical energy, an aerosol-generating system and a computer-readable medium.

Aerosol-generating devices are typically designed as handheld devices that can be used by a user for consuming or experiencing, for instance in one or more usage sessions, aerosol generated from an aerosol-generating substrate or an aerosol-generating article, for example by heating. The aerosol-generating devices the present disclosure pertains to are commonly referred to as heated tobacco products (HTP), heat-not-burn devices, electronic cigarettes and/or vaporisers.

Exemplary aerosol-generating substrates can comprise solid substrate material, such as tobacco material or tobacco cast leaves (TCL) material. The substrate material can, for example, be assembled, often with other elements or components, to form a substantially stick-shaped aerosol-generating article. Such a stick or aerosol-generating article can be configured in shape and size to be inserted at least partially into the aerosol-generating device. The aerosol-generating device may comprise a heating element or heater device for heating the aerosol-generating article and/or the aerosol-generating substrate. The heating element or heater device may be part of the aerosol-generating article and/or the aerosol-generating device. Alternatively or additionally, aerosol-generating substrates can comprise one or more liquids and/or solids, which can, for example, be supplied to the aerosol-generating device in the form of a cartridge or container. Corresponding exemplary aerosol-generating articles can, for example, comprise a cartridge containing or fillable with the liquid and/or solid substrate, which can be vaporized during aerosol consumption by the user based on heating the substrate and/or liquid. Usually, such cartridge or container can be coupled to, attached to or at least partially inserted into the aerosol-generating device. Alternatively, the cartridge may be fixedly mounted to the aerosol-generating device and refilled by inserting liquid and/or solid into the cartridge. The aerosol generated from the aerosol-generating substrate or article may comprise or include one or more of nicotine, aroma, sugar, moisturising agent, preservative, flavouring, for example cocoa, liquorice, menthol and lactic acid or other additives.

For generating the aerosol during use or consumption, heat can be supplied by a heating element, heater device or heat source to heat at least a portion or part of the aerosol-generating substrate. The heating element, heater device or heat source can be arranged in the handheld device or a handheld part of the aerosol-generating device. Alternatively or additionally, at least a part of or the entire heating element or heater device or heat source can be fixedly associated with or arranged within an aerosol-generating article, for instance in the form of a stick or cartridge, which can be attached to and/or powered by the handheld device or handheld part of the aerosol-generating device.

Exemplary heating elements or heater devices can be based on one or more of resistive heating, inductive heating and microwave heating using electrical energy supplied via, drawn from or stored in a battery of the aerosol-generating device. As used herein, a battery of the aerosol-generating device can generally refer to an energy storage of the aerosol-generating device configured to store electrical energy. Accordingly, the term energy storage can include one or more batteries, one or more capacitors, one or more accumulators or other types of energy storage. Also, any reference to a battery herein can include a plurality of batteries.

Typically, aerosol-generating devices comprise an energy storage, for example a battery, providing the electrical energy needed to operate the aerosol-generating device and especially for heating the aerosol-generating substrate and/or article, for example to generate aerosol in one or more usage sessions using one or more aerosol-generating articles. The battery may, for example, be a lithium-ion battery.

As used herein, a usage session may refer to a period of time, during which a user may use the device to generate, consume, experience or inhale aerosol using the aerosol-generating device. Therein, a usage session may be finite. In other words, a usage session may have a start, an end and a duration. The duration of the usage session as measured by time may be influenced by use during the usage session. The duration of the usage session may have a maximum duration determined by a maximum time from the start of the usage session. The duration of the usage session may be less than the maximum time if one or more monitored parameters reaches a predetermined threshold before the maximum time from the start of the usage session. By way of example, the one or more monitored parameters may comprise one or more of: i) a cumulative puff count of a series of puffs drawn by a user since the start of the usage session, and ii) a cumulative volume of aerosol evolved from the aerosol-forming substrate since the start of the usage session.

An energy storage capacity or battery capacity may typically be chosen so that the aerosol-generating device may provide a user with at least a minimum number, for example at least two or more, consecutive usage sessions or experiences without having to recharge the battery or the aerosol-generating device in between. To improve user experience, aerosol-generating devices may usually be designed to only allow a user to start a usage session if the battery contains enough electrical energy to fully complete the usage session. During the lifetime of an energy storage, for example with an increase in the number of charge-discharge cycles, the maximum capacity of the energy storage may decrease or decline. This may be called the aging of the energy storage. The capacity may decrease below the minimum capacity needed to supply the user with at least the minimum number of consecutive usage sessions or experiences without having to recharge the battery or the aerosol-generating device in between. If this happens, the experience of the user may be impaired. Typical ways of determining the current capacity of an energy storage may be intrusive and time consuming and may even necessitate at least partial deconstruction of the aerosol-generating device or the companion device. Determining the current or present capacity of an energy storage is therefore complex and time consuming. The same may apply to the state of health (SOH) of the energy storage, which is determined by comparing the current or present capacity with an original or nominal capacity. This in turn may limit the possibilities of keeping users up-to-date as to the state of their device. Also, lifetime testing procedures on the manufacturer side may be time consuming and expensive.

It may therefore be desirable to provide for an improved way of managing the energy storage of an aerosol-generating device or a companion device configured to charge an aerosol-generating device with electrical energy. Particularly, it may be desirable to improve user experience, for example by providing a user with more detailed information about the state of charge of the devices and/or the state of health of the energy storages of the devices. By giving a user the opportunity to timely replace energy storages, also continuous or future user experience may be improved. This may be achieved by the features described herein.

According to an aspect of the present invention, there is provided a computer-implemented method for estimating a capacity of an energy storage of an aerosol-generating device or a companion device configured to charge an aerosol-generating device with electrical energy, the method comprising: collecting charging profile data of the energy storage, the charging profile data including a charging profile; selecting, in the charging profile data, a data segment of the charging profile; and determining an estimated capacity of the energy storage from the data segment of the charging profile.

The present disclosure may pertain to estimating or determining the capacity, for example the current or present capacity or a future capacity, of the energy storage of the aerosol-generating device or the companion device from charging data, for example charging profile data, of the energy storage. That the capacity may be estimated may mean that the capacity is not directly measured by conventional capacity measuring methods. Instead, the capacity may be estimated or determined indirectly from the charging data, specifically the charging profile data and more specifically from a data segment of the charging profile contained in the charging profile data.

The charging profile data may pertain to charging data of the energy storage. For example, the charging profile data of the energy storage may be collected during the charging of the energy storage with energy, particularly electrical energy. In particular, the charging profile data and/or the charging profile may pertain to current or present charging profile data, meaning up-to-date data, which may, for example, have been collected during the last recharge event of the aerosol-generating device and/or the companion device. The charging profile data may pertain to numerical values of physical properties of the energy storage at different times or points of time during charging. Collecting the charging profile data may therefore include detecting or measuring the respective physical properties of the energy storage at different times or points of time during charging and storing them, for example their numerical values and the respective times or points of time, for example in a data storage of the aerosol-generating device, the companion device or a computing device. The charging profile data may for example pertain to or include one or more of the current or charging current or voltage or charging voltage of the energy storage during charging. The current and/or voltage of or at the energy storage may be measured repeatedly or continuously during charging and the numerical values stored. For example, it may be provided that a numerical value for the respective physical property is collected every second. The charging profile data may therefore include the evolution in time or the characteristic with time or the variation in time of the respective values. The numerical values at different points of time may constitute a charging profile, which may therefore be included in the charging profile data. Such a charging profile, for example pertaining to the current or the voltage, may be visualized as a diagram or a graph, similar to a curve of a mathematical function, for example with an abscissa or x-axis representing time and an ordinate or y-axis representing the numerical values of the physical property, for example current or voltage, of the energy storage.

According to the present disclosure, an estimated capacity of the energy storage may be determined from a data segment of the charging profile. A data segment may pertain to a part or a subset or a range of the collected charging profile data that is used for determining the estimated capacity of the energy storage. The data segment may comprise less data than the collected charging profile data. Particularly, the data segment may not comprise all of the collected charging profile data, but only a fraction, preferably a continuous fraction, of the collected charging profile data. The data segment may, for example, include only the charging profile data collected in a period or range of time, wherein the period or range of time is shorter than the period or range of time of the whole charging profile data set or charging event. The data segment may comprise charging profile data from consecutive or subsequent times or points in time at which the physical property has been measured. Therefore, the data segment according to the present disclosure may not contain disconnected or separate data points, preferably with regard to time. According to the present disclosure, such a data segment of the charging profile may be enough to reliably determine the estimated capacity of the energy storage without having to use the full charging profile or all of the charging profile data. By using only a data segment of the charging profile data, the accuracy of the estimated capacity of the energy storage may be increased. Simultaneously, the computation power needed to determine the capacity from the data segment may be decreased, making implementation of the present disclosure into hand-held devices like aerosol-generating devices and companion devices feasible.

To further increase the accuracy of the estimated capacity of the energy storage, the estimated capacity of the energy storage may not be determined only from the data segment of the charging profile but may also be determined from a number of usage sessions provided to a user. In other words, the method may comprise determining an estimated capacity of the energy storage from the data segment of the charging profile and a number of usage sessions, preferably the cumulative usage sessions, provided to a user. The number of usage sessions provided to a user preferably pertains to the usage sessions, preferably the cumulative usage sessions, provided from the current energy storage, particularly when the energy storage is replaceable or removable. The number of usage sessions may correlate very closely to the charge-discharge cycles of the energy storage and may therefore be a suitable measure of energy storage lifetime progression. For example, a usage session may provide for a specific temperature profile to a heater, thereby requiring a specific, repeated electric power consumption profile, which in turn can provide for a suitable data set on power consumption that can be correlated to historic consumption data. As explained in further detail below, the training data used to establish the models used in the present disclosure may also be matched to reference data through the number of usage sessions provided to a user. The number of usage sessions provided to a user may therefore provide an even stronger link to the reference data and thereby increase the accuracy of the determination. The usage sessions provided to a user may, on the one hand, pertain to the usage sessions provided by the aerosol-generating device by heating or otherwise aerosolizing an aerosol-generating article or substrate. On the other hand, as an example, the usage sessions provided to a user may also pertain to the number of times a companion device was used to recharge the aerosol-generating device with enough energy so that the aerosol-generating device may provide the user with a usage session. Therefore, the number or amount of usage sessions provided to a user may be a measure for both the lifetime progression of the energy storage of the aerosol-generating device as well as the companion device.

The charging profile and/or the charging profile data may pertain to any physical property of the energy storage or battery during charging that is characteristic for the charging process of the energy storage. The charging profile and/or the charging profile data may, for example, be at least one of a charging voltage profile or a charging current profile of the energy storage. In the following, the present disclosure will focus on the examples of current and voltage, but other physical properties of the energy storage may also be used in addition or as an alternative.

As mentioned above, when determining or estimating energy storage capacity in an aerosol-generating device or a companion device, typically intrusive or semi-intrusive methods may need to be employed. For example, it may be necessary to open the device housing, unsolder the battery, remove the battery from the housing and perform testing on the battery. This may be called an intrusive method of capacity determination. Alternatively, it may be necessary to open the device housing and connect a testing apparatus to the battery, for example a battery cycler, which may still remain in the device housing. This approach may be called semi-intrusive. Both intrusive and semi-intrusive methods may need to be performed on the battery level, meaning that testing equipment may have to be directly connected to the battery itself. These conventional approaches may be very time-consuming and therefore limiting. In contrast, according to the present disclosure, the charging profile data may be collected unintrusively at a device level. This may mean that the charging profile data may be collected during normal use of the aerosol-generating device and/or the companion device. No opening of the housing, no removal of the battery, and no unsoldering of the energy storage may be necessary. It may also not be necessary to connect any testing equipment to the energy storage or battery itself. According to the present disclosure, the charging profile data may therefore be collected with the device housing fully closed or intact. No additional testing equipment may be necessary. The current and/or the voltage at the energy storage during charging may be directly determined from the charging circuit, which may be configured as an inter-integrated circuit (I2C), and which may be configured to determine the charging profile data, which may be read from the charging circuit by a control circuitry or processing circuitry and/or a controller of the device. The charging profile data may therefore be collected continuously during the use and/or the lifetime of the aerosol-generating device and/or the companion device, particularly without having to subject the device to specific capacity testing.

In the present disclosure, the focus may lie on analyzing charge-discharge cycles of the energy storage during use. When looking at charging profiles of energy storages, such as batteries, the present disclosure may pertain to constant current regulation modes or phases and/or constant voltage regulation modes or phases. Pre-charge modes or phases may, conversely, not be further considered. The charging profile data and/or the charging profiles according to the present disclosure therefore pertain to constant current regulation modes or phases and/or constant voltage regulation modes or phases. For instance, the charging profile data and/or the charging profiles according to the present disclosure may at least comprise the transition from the constant current regulation mode or phase to the constant voltage regulation mode or phase. In typical charging profiles of energy storages, particularly in said modes or phases, the voltage at the energy storage gradually increases until a plateau is reached, from which time on the voltage remains approximately constant. The point of the charging profile at which this plateau in voltage is reached may be called constant voltage point of the charging profile (CV). Conversely, the current in typical charging profiles of energy storages may start at a plateau and be approximately constant and may then start to drop. The point of the charging profile at which the current starts dropping may be called constant current point of the charging profile (CC). When current and voltage charging profiles of the same energy storage and the same charging event are evaluated, the point in time where the approximately constant current starts to drop and the voltage stops increasing and reaches the plateau may be simultaneous. In other words, the constant voltage point and the constant current point of one single charging event are simultaneous. At this point in time, the respective charging profile may have a kink or a crease or a bend or a corner point. This may be immediately apparent when the respective charging profile is visualized as a graph or a curve.

It may be provided that the data segment of the charging profile is selected so that the data segment lies next to a corner point of the charging profile. In other words, it may be provided that the data segment of the charging profile is selected so that the data segment lies before or in front of, preferably directly before or in front of, a constant voltage point of the charging profile. At the same time, it is possible that the data outside of the data segment adjacent to the constant voltage point is not considered or excluded for the battery capacity determination, thereby reducing the amount of data that needs to be processed. Alternatively, it may be provided that the data segment of the charging profile is selected so that the data segment lies behind or after, preferably directly behind or after, a constant current point of the charging profile. At the same time, it is possible that the data outside of the data segment adjacent to the constant current point is not considered or excluded for the battery capacity determination, thereby reducing the amount of data that needs to be processed. This may mean that the data segment used in determining the capacity of the energy storage includes, preferably exclusively includes, data collected before the corner point of the charging profile, for example before the constant voltage point. This may also mean that the data segment used in determining the capacity of the energy storage includes, preferably exclusively includes, data collected after the corner point of the charging profile, for example after the constant current point. The numerical value of the voltage or the current directly at the corner point or constant voltage point or constant current point may be included in or excluded from the data segment. While it may be possible to use other data segments of the charging profile, using a data segment next to a corner point, for example the constant voltage point or the constant current point of the charging profile, may result in improved accuracy of the results.

As explained above, the data segment may include only part of the total charging profile data. For example, the data segment of the charging profile may be selected so that the data segment includes at most 30% or at most 25% or at most 20% or at most 15% or at most 10% or at most 5% of a time period of a time duration of the total charging profile, preferably of the total time period of the charging profile. The total time period or the total time duration of the charging profile may describe the total time elapsing between the begin and the end of a charging event. When an energy storage is recharged from empty to full, the total time period or the total time duration of the charging profile may describe the sum of the times needed for the constant current regulation mode or phase and the constant voltage regulation mode or phase during the charging event. However, the total time period or the total time duration of the charging profile may also describe the time elapsing between the beginning and the end of the charging event regardless of how much of the total capacity of the energy storage is recharged in this event. The respective time may therefore also describe the time between establishing and separating an electrical connection between the aerosol-generating device or the companion device and a source of electrical energy, for example a charger or the companion device. In absolute values, the data segment of the charging profile may be selected so that the data segment represents a time period of a time duration of the charging profile of at most 1500 seconds or at most 1000 seconds or at most 750 seconds or at most 500 seconds or at most 250 seconds or at most 100 seconds or at most 60 seconds or at most 30 seconds or at most 15 seconds. As the time necessary to fully recharge an energy storage may also depend on the total capacity of the energy storage itself, it may be necessary to choose data segments representing longer times for energy storages of greater capacity and vice versa.

A charging event according to the present disclosure may be the act of recharging the aerosol-generating device or the companion device, for example from an external power source or between each other. A charging event may describe both a full recharge of the respective device, meaning recharging the energy storage from empty or functionally empty to full capacity, or a partial recharge of the respective device, for example when a user plugs in the respective device only for a short amount of time that is not enough to fully recharge the device or when the device is not empty or functionally empty when recharging begins. The method according to the present disclosure may be successfully performed even with partial charging profiles resulting from partial recharges, so long as an appropriate amount of data close to the corner point of the charging profile is acquired. In other words, the amount of data acquired during the partial recharge may have to be enough to be able to select the data segment as described herein. That is why defining the length of the period of time covered by the data segment both as a percentage of the total time of the charging event and as an absolute time is sensible, as it may be more appropriate to select the data segment covering a fixed amount of time when only a partial recharge is available. On the other hand, when a full recharge is performed and therefore the complete charging profile is available, it may be more appropriate to choose the length of time covered by the data segment according to the percentage as given above. Also, when an accurate estimation of the capacity of the energy storage is desired, for example during testing or in maintenance or troubleshooting, it may be helpful to perform a full recharge and collect charging profile data comprising a full charging profile.

The actual determination of the capacity or the estimated capacity of the energy storage from the data segment may be done in a plurality of different ways. For example, the graphs or curves representing the data segment may be compared to reference graphs or curves representing different predetermined capacities of the energy storage and the estimated capacity may be determined through a measure of similarity between the compared graphs or curves. Alternatively, the method may comprise fitting the data segment of the charging profile to a mathematical function and determining the capacity or the estimated capacity of the energy storage from the mathematical function. For example, a mathematical function fitting the data segment may be determined through regression analysis. The mathematical function may be, for example, a polynomial function, preferably a polynomial function of one of second, third and fourth degree. The specific function and/or order used may depend on the specific form of the graph or curve representing the data segment so that the specific function and/or order may be different for each data segment. The capacity or the estimated capacity of the energy storage may then be determined from the mathematical function. For example, determining the capacity or the estimated capacity from the function may be achieved by comparison of the mathematical function to predetermined functions established from charging events of energy storages of known capacity. In particular, the mathematical function may comprise one or more summands with a coefficient each. The values of the one or more coefficients may then be used for determining the capacity or the estimated capacity of the energy storage, in particular through comparison of the coefficients with the coefficients of mathematical functions established from charging events of energy storages of known capacity. Models that may be used for the determination of the capacity or the estimated capacity from the data segment may include linear regression, gradient boosting, AdaBoost, Random Forest, LightGBM, XGBoost and Support Vector Regression (SVR). These models may be implemented to determine the estimated capacity, for example by comparison with previously collected training data.

The method according to the present disclosure may pertain solely to the determination of the capacity or the estimated capacity of the energy storage, for example by utilizing previously determined models based on training data. However, the present disclosure also pertains to the provision of this training data and the establishing of models. The method may therefore comprise collecting training charging profile data of the energy storage, the training charging profile data including a training charging profile, selecting, in the training charging profile data, a data segment of the training charging profile, collecting energy storage capacity data, and correlating the data segment of the training charging profile with the energy storage capacity data. These steps may, for example, be performed prior to the steps previously explained. The training charging profile data and/or the training charging profile may pertain to historic data, meaning to data that may have been collected over a period of time in the past. The data may therefore be used to establish a correlation between the data segment and the capacity of the energy storage which may then be used to determine an estimated capacity based on current or present data and the correlation established through the training data. The data segment of the training charging profile may correspond to or be similar to the data segment as previously explained, particularly the data segment of the current or present charging profile.

To be able to establish a correlation between the data segment and the energy storage capacity data, energy storage capacity data may be collected. Energy storage capacity data may describe capacity values of the energy storage. The energy storage capacity data may be collected intrusively at an energy storage level or unintrusively at the device level. For example, the previously explained intrusive conventional methods of capacity determination may be used to establish the energy storage capacity data as reference data for the determination according to the present disclosure. The energy storage may be extracted from the aerosol-generating device or companion device and subjected to testing on an energy storage cycler or battery cycler which subjects the energy storage or battery to repeated charge-discharge cycles and measures the remaining capacity after each cycle. However, to further refine the method, also unintrusively collected data may be used. As the unintrusive collection of data may be less expensive and faster than intrusive collection, this may result in a significant increase in the amount of data available. Energy storage capacity data collected unintrusively at device level may, for example, come from accelerated life testing (ALT), for example from aerosol-generating devices being subjected to repeat uses in laboratory conditions. These may, for example, include the repeated production or generation of aerosol from aerosol-generating substrates or articles. As an alternative, substitutes for aerosol-generating substrates or articles having the same or nearly the same properties when being used in an aerosol-generating device may be employed. Repeatedly using the aerosol-generating device in laboratory conditions like this may be used to collect the energy storage capacity data used in the present disclosure. As the aerosol-generating device is actually used and therefore the energy storage is subjected to charge-discharge cycles similar to use by users in the field, very accurate energy storage capacity data linked to the precise amount of uses or usage sessions provided is gained. This gathered or measured reference data of a specific battery may be stored in a database and linked to a make, brand, identifier or serial number of a specific battery or battery type, for use within the context of the herein described method, system, and device.

The data segment of the training charging profile may be correlated with the energy storage capacity data to establish a correlation that may be used to infer the capacity or estimated capacity of the energy storage from another, similar data segment and the correlation alone, without the energy storage capacity data. In other words, this correlation may then be used in the previously described step of determining the estimated capacity of the energy storage from the data segment of the charging profile, preferably the current or present charging profile.

To establish a context or a relationship between the training charging profile data and the energy storage capacity data, it may be provided that the energy storage capacity data is collected immediately before and/or after the training charging profile data. For example, the energy storage capacity data is collected immediately before or immediately after a charging event in which the training charging profile data is collected. In this way, it may be ensured that the training charging profile data fits or matches the energy storage capacity data. The method may also include matching the data segment of the training charging profile with the energy storage capacity data by the number of usage sessions provided to a user by the aerosol-generating device or the companion device. The number of usage sessions that have already been provided to the user may be used to provide a link between the training charging profile data and the energy storage capacity data. For example, if training charging profile data of an energy storage is collected from a device that has already provided X usage sessions to one or more users, this data may be matched to energy storage capacity data collected from a device that has also provided a similar number of X usage sessions. The respective link or correlation established between the energy storage capacity data and the training charging profile data, in particular along with the amount of usage sessions provided, can then be followed in the other direction by using charging profile data, in particular along with the amount of user sessions provided, to infer the estimated energy storage capacity.

The method according to the present disclosure may pertain to only one model of aerosol-generating device and/or companion device or may pertain to a plurality of models using the same type of energy storage. The method according to the present disclosure may have to be separately implemented for different models of aerosol-generating device and/or companion device, especially for different device models using different energy storages.

As already mentioned, the method may comprise establishing a capacity estimation model from the correlation of the data segment of the training charging profile and the energy storage capacity data. The model may also use the amount of usage sessions provided to a user as an additional parameter. The model may use or may be based on any of linear regression, gradient boosting, AdaBoost, Random Forest, LightGBM, XGBoost and Support Vector Regression (SVR). The model may thus be configured to determine the estimated capacity of the energy storage from the correlation between the training charging profile and the energy storage capacity data. The input of the model may be the data segment of the charging profile, in particular the current or present charging profile, and optionally also the amount of usage sessions provided to a user.

The capacity estimation model may be established using at least one of an (artificial) intelligence engine or intelligence network or machine learning. For example, a convolutional neural network (CNN), random forest, decision forest, decision tree etc. may be employed in correlating the energy storage capacity data and the training charging profile data to establish the model. These engines or networks may be trained on large data sets beforehand so that they enable precise determining of estimated capacities based on the data available on each and every one of the aerosol-generating devices or companion devices.

The method may also comprise smoothing the charging profile data and/or the training charging profile data. For this purpose, any suitable mathematical filter may be used. For example, the data may be smoothed by applying a Savitzky-Golay filter. It may also be provided that the charging profile data and/or the training charging profile data is smoothed more than once, for example by applying a filter more than once. For example, it may be provided that a Savitzky-Golay filter is applied to the data at least twice or at least three times. This may result in increased precision of the data without distorting a tendency of the signal, which may in turn increase the accuracy of the estimated capacity.

To further increase the quality of the data used according to the present disclosure, the method may comprise cleaning the charging profile data and/or the training charging profile data. This may preferably be achieved by at least one of interpolating gaps and removing undefined or unrepresentable values, for example NaN (Not a Number) values. Preferably, any values to be removed may be removed before gaps are interpolated. This data pre-processing ensures high accuracy in determining the estimated capacity.

To be able to provide a user with accurate and up-to-date capacity information, it may be provided that the method comprises collecting and storing charging profile data of the energy storage each time the aerosol-generating device or the companion device is charged. In this way, up-to-date charging profile data is always available and the current capacity of the energy storage may be readily determined from the latest charging profile data collected. This data may also be collected by the manufacturer for usage statistics or maintenance timing.

Additionally, when charging profile data is collected over a plurality of charging events, it may be possible to extrapolate the estimated capacity of the energy storage into the future. It may therefore be provided that the method comprises selecting, from the plurality of stored charging profile data, a data segment of each charging profile, and predicting, from the plurality of data segments of the charging profiles, a capacity of the energy storage at a point of time in the future. The point of time in the future may pertain to one day or three days or one week or two weeks or one month or three months or six months or twelve months in the future. For example, the mathematical function may be fit to the data segments of all the available charging profiles. For each of the data segments, this may result in one set of coefficients of the mathematical function. It may then be possible to analyse how the value of the coefficients change over time. A future capacity of the energy storage may then be extrapolated from the evolution in time of the coefficients of the mathematical function. Such a predicted capacity in the future may be used to alert the user of the predicted deterioration of the capacity which may fall below a threshold capacity, for example a threshold capacity enabling the provision of a minimum number of usage sessions to the user. If this is predicted, the method may comprise displaying a message or other information to the user informing them of the predicted capacity and/or the point of time at which the threshold capacity may be reached.

In general, the present disclosure may be used to provide the user with a plurality of information with regard to the capacity of the energy storage. For example, the method may comprise calculating and displaying to a user and/or storing a current state of health (SoH) of the energy storage from the current capacity of the energy storage, or a timely or historic evolution of the state of health (SoH) as a curve. The current or present capacity of the energy storage may be the capacity as determined by the method of the present disclosure, particularly using the current or present charging profile data. The state of health of the energy storage may be defined as the current or present capacity of the energy storage divided by the original or nominal capacity of the energy storage. For example, the state of health of the energy storage may be presented as a percentage representing how much of the original capacity is still available in the fully charged energy storage.

Further, the method may comprise calculating and displaying to a user and/or storing a future state of health (SoH) of the energy storage from the predicted capacity of the energy storage. The method may also comprise calculating and displaying to a user and/or storing a point of time or a date in a future at which the capacity and/or the state of health (SoH) of the energy storage will fall under a predetermined threshold with a predetermined degree of certainty. The predetermined threshold may again be represented by a threshold capacity, for example a threshold capacity enabling the provision of a minimum number of usage sessions to a user. With a predetermined degree of certainty may mean with a certainty of 95% or 90% or 85% or 80% or 75% or 70%. Additionally, the method may comprise calculating and displaying to a user and/or storing whether or not the energy storage needs to be replaced; and/or a point of time or a date in the future at which the energy storage will need to be replaced with a predetermined degree of certainty. Whether or not the energy storage needs to be replaced may also be judged by whether or not the capacity of the energy storage remains above the threshold capacity. An energy storage whose capacity lies below the threshold capacity may need to be replaced.

Displaying to a user may comprise visual and/or acoustic presentation of information. It may further comprise transferring the information to another device, for example a computing device and then displaying the information to the user on the computing device. The method may further comprise displaying and/or storing the respective information as at least one of a bar, a bar chart, a pie chart, a curve, a percentage of an original value, a countdown number or a pictogram. All of these visualizations may be useful to inform the user at which point of its lifetime the energy storage of their device is presently at or will be at the point of time in the future.

The method may further comprise sending the estimated capacity or the predicted capacity of the energy storage to a server device, for example a web server, for data analysis and/or remote maintenance. The server device may, for example, be maintained by the manufacturer of the aerosol-generating device and/or companion device. The data sent to the server device may, for example, be used to analyse the lifetime of the energy storage in actual use in the devices. Such an analysis may therefore help to improve product quality. The data may also be used for remote maintenance. For example, when the data transmitted to the server device indicates that there is or there will be a problem with the energy storage, the server device may send a message to the user, for example via the aerosol-generating device or the companion device or via other customer contact information provided by the user. The message may inform the user of the need to replace the energy storage or of the predicted future need to replace the energy storage.

According to another aspect of the present disclosure, there is provided an aerosol-generating system, comprising at least one of an aerosol-generating device, preferably comprising an aerosol-generating substrate or article, a companion device configured to charge an aerosol-generating device with electrical energy, and a computing device, wherein the at least one of the aerosol-generating device, the companion device, and the computing device includes a processing circuitry including at least one processor, and wherein the processing circuitry is configured to perform steps, preferably all of the steps, of the method according to the present disclosure. All of the features, functions and advantages of the method according to the present disclosure are also applicable to the aerosol-generating system and vice versa.

The aerosol-generating system may for example comprise a firmware being executed by the processing circuitry. The firmware may comprise a program code that causes the processing circuitry to perform steps, preferably all of the steps, of the method according to the present disclosure.

The method according to the present disclosure may be performed on the aerosol-generating device to estimate the capacity of the energy storage of the aerosol-generating device itself. On the other hand, the method according to the present disclosure may also be performed on the aerosol-generating device to estimate the capacity of the companion device. Conversely, the method according to the present disclosure may be performed on the companion device to estimate the capacity of the energy storage of the companion device itself. On the other hand, the method according to the present disclosure may also be performed on the companion device to estimate the capacity of the aerosol-generating device. The method according to the present disclosure may also be performed on the computing device to estimate the capacity of the energy storage of the aerosol-generating device and/or the companion device. Where necessary, the charging profile data may be transferred between the mentioned devices.

The computing device may be any computing device suitable to enter into a data connection with the aerosol-generating device and/or the companion device. For example, the computing device may be at least one of a smartphone, a tablet computer, a personal computer, and a server device.

According to another aspect of the present disclosure, there is provided a computer-readable medium, for example a non-transitory computer-readable medium, wherein computer-executable program code is stored on the medium, and wherein the program code, when executed on a computing device or controller, causes the computing device or controller to perform steps, preferably all of the steps, of the method according to the present disclosure. All of the features, functions and advantages of the method and of the aerosol-generating system according to the present disclosure are also applicable to the computer-readable medium and vice versa. The controller on which the program code may be executed may be, for example, part of the processing circuitry of one of the aerosol-generating device, the companion device or the computing device.

The invention according to the present disclosure has been described using the example of an aerosol-generating system, i.e. an aerosol-generating device, a companion device and a computing device. However, the method described herein may be performed on any electrical device, for example portable or hand-held electrical device, having an energy storage or battery. The method is therefore not limited to the application to aerosol-generating devices, companion devices or computing devices. The method and the computer-readable medium may therefore also be claimed in broader scope without reference to these specific devices. All of the features, functions and advantages as well as further developments of the method of the present disclosure are therefore also applicable to other electrical devices, for example portable or hand-held electrical devices having an energy storage or battery.

The invention is defined in the claims. However, below there is provided a non-exhaustive list of non-limiting examples. Any one or more of the features of these examples may be combined with any one or more features of another example, embodiment, or aspect described herein.
Example 1. A computer-implemented method for estimating a capacity of an energy storage of an aerosol-generating device or a companion device configured to charge an aerosol-generating device with electrical energy, the method comprising:
collecting charging profile data of the energy storage, the charging profile data including a charging profile,
selecting, in the charging profile data, a data segment of the charging profile, and
determining an estimated capacity of the energy storage from the data segment of the charging profile.
Example 2. The method according to Example 1, wherein the charging profile is at least one of a charging voltage profile or a charging current profile of the energy storage.
Example 3. The method according to any one of the previous Examples, wherein the charging profile data is collected unintrusively at a device level.
Example 4. The method according to any one of the previous Examples, wherein the data segment of the charging profile is selected so that the data segment lies next to a corner point of the charging profile.
Example 5. The method according to any one of the previous Examples, wherein the data segment of the charging profile is selected so that the data segment lies
before, preferably directly before, a constant voltage (CV) point of the charging profile; or
after or behind, preferably directly after or behind, a constant current (CC) point of the charging profile.
Example 6. The method according to any one of the previous Examples, wherein the data segment of the charging profile is selected so that the data segment includes at most 30% or at most 25% or at most 20% or at most 15% or at most 10% or at most 5% of a time period of a time duration of the total charging profile, preferably of the total time period of the charging profile.
Example 7. The method according to any one of the previous Examples, wherein the data segment of the charging profile is selected so that the data segment represents a time period of a time duration of the charging profile of at most 1500 seconds or at most 1000 seconds or at most 750 seconds or at most 500 seconds or at most 250 seconds or at most 100 seconds or at most 60 seconds or at most 30 seconds or at most 15 seconds.
Example 8. The method according to any one of the previous Examples, comprising
fitting the data segment of the charging profile to a mathematical function; and
determining the capacity of the energy storage from the mathematical function.
Example 9. The method according to the previous Example, wherein the mathematical function is a polynomial function, preferably a polynomial function of one of second, third and fourth degree.
Example 10. The method according to any one of the previous Examples, comprising determining an estimated capacity of the energy storage from the data segment of the charging profile and a number of usage sessions provided to a user.
Example 11. The method according to any one of the previous Examples, comprising
collecting training charging profile data of the energy storage, the training charging profile data including a training charging profile,
selecting, in the training charging profile data, a data segment of the training charging profile,
collecting energy storage capacity data, and
correlating the data segment of the training charging profile with the energy storage capacity data.
Example 12. The method according to the previous Example, including matching the data segment of the training charging profile with the energy storage capacity data by the number of usage sessions provided to a user by the aerosol-generating device or the companion device.
Example 13. The method according to any one of the previous Examples 11-12, wherein the energy storage capacity data is collected intrusively at an energy storage level or unintrusively at a device level.
Example 14. The method according to any one of the previous Examples 11-13, comprising establishing a capacity estimation model from the correlation of the data segment of the training charging profile and the energy storage capacity data.
Example 15. The method according to the previous Example, comprising establishing the capacity estimation model using at least one of an intelligence engine, an intelligence network, and machine learning.
Example 16. The method according to any one of the previous Examples, comprising smoothing the charging profile data, preferably by applying a Savitzky-Golay filter.
Example 17. The method according to any one of the previous Examples, comprising cleaning the charging profile data, preferably by one of interpolating gaps and removing undefined or unrepresentable values.
Example 18. The method according to any one of the previous Examples, comprising collecting and storing charging profile data of the energy storage each time the aerosol-generating device or the companion device is charged.
Example 19. The method according to the previous Example, comprising selecting, from the plurality of stored charging profile data, a data segment of each charging profile, and predicting, from the plurality of data segments of the charging profiles, a capacity of the energy storage at a point of time in a future.
Example 20. The method according to the previous Example, wherein the point of time is one day or three days or one week or two weeks or one month or three months or six months or twelve months in the future.
Example 21. The method according to any one of the previous Examples, comprising calculating and displaying to a user and/or storing at least one of:
a current state of health (SoH) of the energy storage from a current capacity of the energy storage;
a future state of health (SoH) of the energy storage from the predicted capacity of the energy storage;
a point of time or a date in a future at which the capacity and/or the state of health (SoH) of the energy storage will fall under a predetermined threshold with a predetermined degree of certainty;
whether or not the energy storage needs to be replaced; and/or
a point of time or a date in a future at which the energy storage will need to be replaced with a predetermined degree of certainty.
Example 22. The method according to the previous Example, comprising displaying and/or storing the respective information as at least one of a bar, a bar chart, a pie chart, a curve, a percentage of an original value, a countdown number or a pictogram.
Example 23. The method according to any one of the previous Examples, comprising sending the estimated capacity of the energy storage to a server device, for example a web server, for data analysis and/or remote maintenance.
Example 24. An aerosol-generating system, comprising at least one of an aerosol-generating device, preferably comprising an aerosol-generating substrate or article, a companion device configured to charge an aerosol-generating device with electrical energy, and a computing device, wherein the at least one of the aerosol-generating device, the companion device, and the computing device includes a processing circuitry including at least one processor, and wherein the processing circuitry is configured to perform steps of the method according to any of the previous Examples.
Example 25. The aerosol-generating system according to the previous Example, wherein the computing device is at least one of a smartphone, a tablet computer, a personal computer, and a server device.
Example 26. A computer-readable medium, wherein computer-executable program code is stored on the medium, and wherein the program code, when executed on a computing device, causes the computing device to perform steps of the method according to any one of the previous Examples 1-23.

Examples will now be further described with reference to the figures in which:

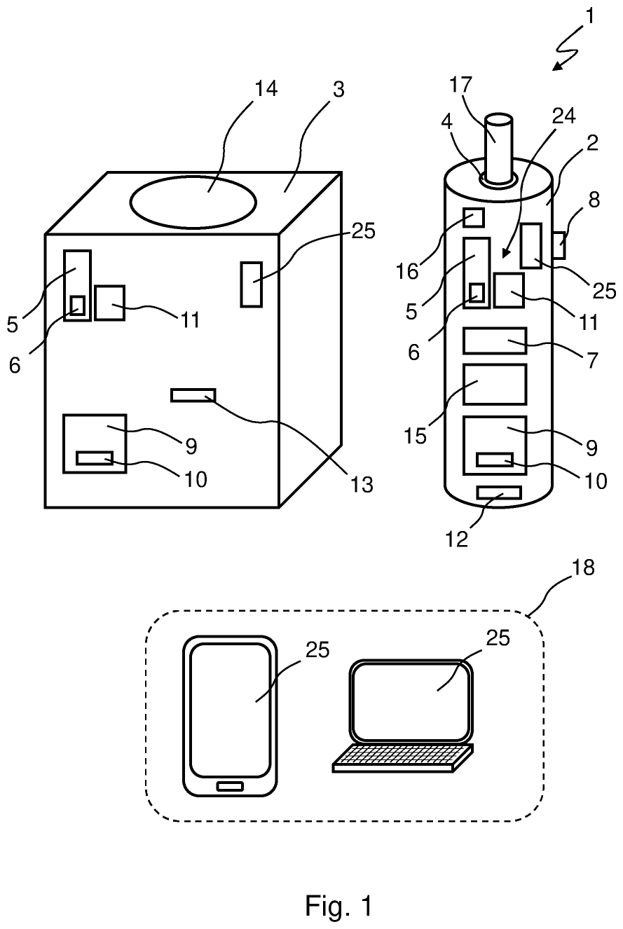

FIG. 1 shows an aerosol-generating system;

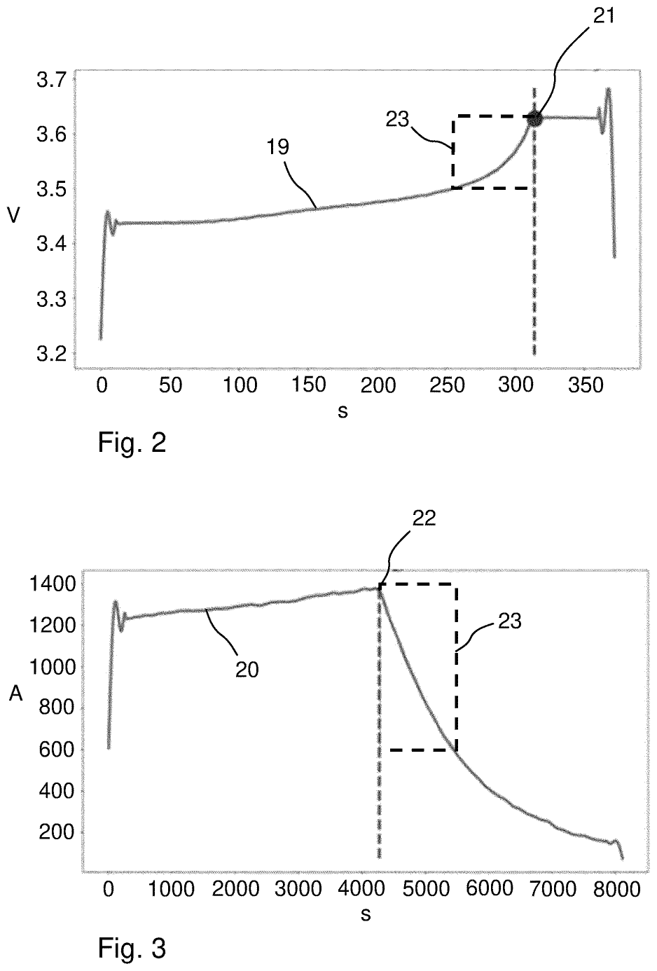

FIG. 2 shows a charging voltage profile of the energy storage of an aerosol-generating device or a companion device;

FIG. 3 shows a charging current profile of the energy storage of an aerosol-generating device or a companion device; and

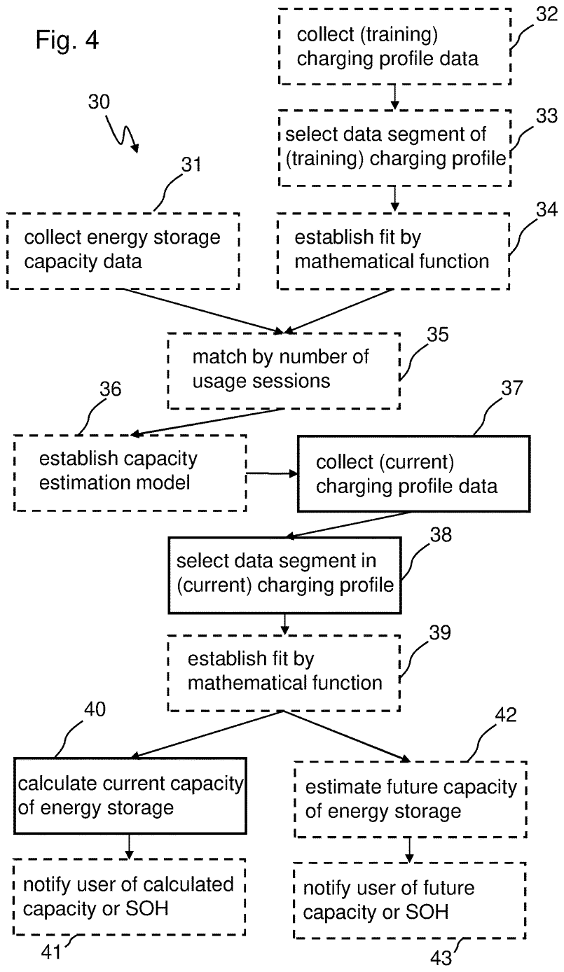

FIG. 4 shows a flowchart of the method.

The figures are schematic only and not to scale.

FIG. 1 shows an aerosol-generating system 1 for generating aerosol, for example for consumption or inhalation by a user in one or more usage sessions. The system 1 may comprise at least one of an aerosol-generating device 2 for generating aerosol, a companion device 3 for at least partially receiving the aerosol-generating device 2 and/or an external computing device 18. The companion device 3 may be a charging device for charging the aerosol-generating device 2 and/or an energy storage or battery thereof.

The aerosol-generating device 2 may comprise an insertion opening 4 for at least partially inserting an aerosol-generating article 17. The aerosol-generating article 17 may comprise an aerosol-forming substrate, such as a tobacco containing substrate, and/or a cartridge comprising a liquid, for example a liquid that can be aerosolized for inhalation.

The aerosol-generating device 2 may further include processing circuitry 24 or control circuitry 24 with at least one controller 5 and one or more processors 6. For generating the aerosol during use or consumption of the aerosol-generating article 17, the aerosol-generating device 2 may comprise at least one heating element 7 or heater device for applying heat to at least a portion of the aerosol-generating article 17. Instead of the heating element 7, an ultrasonic device (not shown) may also be used to generate aerosol from the aerosol-generating article 17. The processing circuitry 24 and/or the controller 5 may be configured to control actuation, activation and/or deactivation of at least one heating element 7 or ultrasonic device.

For powering the at least one heating element 7 with electrical power, the aerosol-generating device 2 may further comprise at least one energy storage 15, for example in the form of a battery, for storing electrical energy or power. The aerosol-generating device 2 may further comprise at least one electrical connector 12 for coupling to a corresponding at least one electrical connector 13 of the companion device 3 and/or an electrical connector of an external power supply (not shown), e.g., a USB charger. For example, when the aerosol-generating device 2 is at least partially inserted into the opening 14 of the companion device 3, the one or more electrical connectors 12 of the aerosol-generating device 2 may be coupled with the one or more electrical connectors 13 of the companion device 3 to charge the at least one energy storage 15 of the aerosol-generating device 2. Alternatively, the electrical connector 12 of the aerosol-generating device 2 may be coupled with one or more electrical connectors 13 of the computing device 18. The electrical connector 13 of the computing device 18 may, for example, be a plug attached to a cable suitable for data transfer between the aerosol-generating device 2 and the computing device 18.

The aerosol-generating device 2 may further comprise a communications arrangement 9 or communication circuitry 9 with one or more communications interfaces 10 for communicatively coupling the aerosol-generating device 2 with the companion device 3 and/or the computing device 18, for example, via an Internet connection, a wireless LAN connection, a WiFi connection, a Bluetooth connection, a mobile phone network, a mobile data connection for example but not limited to a 3G/4G/5G connection, an edge connection, an LTE connection, a BUS connection, a wireless connection, a wired connection, an optical data connection such as but not limited to IrDa, a radio connection, a near field connection, and/or an loT connection.

The aerosol-generating device 2 may further comprise a data storage 11 for storing information, program code or data. Data storage 11 may also store collected values of charging profile data and/or one or more mathematical functions or formulas, software and computer instructions that can be executed by the controller 5 and/or processing circuitry 24. One or more sensors 16 may be arranged on, at or in the aerosol-generating device 2 to collect data. One or more of the sensors 16 may for example be temperature sensors, strain sensors, accelerometers or any other suitable sensors.

The aerosol-generating device 2 may further comprise user interface components, for example comprising an input element or input device 8, for example in the form of a pushbutton or a capacitive button. The input device 8 may be used as a power button to activate or deactivate the heating element 7 or ultrasonic device for aerosol generation thereby to activate or deactivate the aerosol-generating device 2. Upon activation of the aerosol-generating device 2, the heating element 7 may be activated and heat may be applied to at least a part of the aerosol-generating article 17, such that aerosol can be generated for consumption or inhalation by the user, for example in a usage session. The aerosol generating device 2 and/or the companion device 3 may each comprise a user interface comprising one or more output elements, such as a display and/or one or more LEDs, for outputting a signal and/or displaying information to a user.

FIGS. 2 and 3 each show exemplary visualizations of charging profile data, specifically a charging profile. Both charging profiles may pertain to the constant current regulation mode or phase and the constant voltage regulation mode or phase of battery charging. Pre-charging and other modes of charging are not shown and may not be of interest for the present disclosure.

In FIG. 2, a charging voltage profile 19 may be shown as a diagram or graph with the time elapsed in the charging event shown on the abscissa or x-axis in seconds and the voltage or charging voltage at the energy storage 15 shown on the ordinate or y-axis in volts. As can be seen in the charging voltage profile 19, the charging voltage may increase during the charging until it reaches a plateau and stays approximately constant. Outliers at the beginning and at the end of the charging profile, caused by establishing and disengaging the connection to a power source, may be ignored. The point in the charging voltage profile 19 at which the plateau is reached may be called the constant voltage point 21 (CV).

In FIG. 3, a charging current profile 20 may be shown as a diagram or graph with the time elapsed in the charging event shown on the abscissa or x-axis in seconds and the current or charging current at the energy storage 15 shown on the ordinate or y-axis in amperes. As can be seen in the charging current profile 20, the charging current may start at an approximately constant value during the charging and may then suddenly start to drop off. Outliers at the beginning and at the end of the charging profile, may again be ignored. The point in the charging current profile 20 at which the current starts to drop off may be called the constant current point 22 (CC).

The constant voltage point 21 and the constant current point 22 of the charging profiles may each represent a kink or a crease or a bend or a corner point of the respective graphs or diagrams. In both the charging voltage profile 19 of FIG. 2 and the charging current profile 20 of FIG. 3, a data segment 23 that may be selected for further use in the method according to the present disclosure is marked by the dashed line box. The data segment 23 may be selected so that the data segment 23 lies next to, preferably directly next to, a kink or a crease or a bend or a corner point of the respective graphs or diagrams of the charging profiles. For example, the data segment 23 may lie directly before the constant voltage point 21 (as shown in FIG. 2) or directly behind the constant current point 22 (as shown in FIG. 3) in the respective charging profiles. Therefore, the data segment 23 may begin with the constant current point 22 or may end with the constant voltage point 21.

As can be seen from the abscissa or x-axis, the time elapsing in the charging profiles according to FIG. 2 and FIG. 3 may be very different. For example, the time needed for the full charging event according to FIG. 2 may be around 360 seconds, while the time needed for the full charging event according to FIG. 3 may be around 8000 seconds. This difference may be caused by a different maximum capacity of the energy storage 15 being charged according to FIG. 2 and the one being charged according to FIG. 3. The maximum capacity of the energy storage 15 whose charging event is shown in FIG. 3 may be greater than the capacity of the energy storage 15 whose charging event is shown in FIG. 2. Therefore, the time needed to fully charge the energy storage 15 according to FIG. 3 is greater than for the one according to FIG. 2. This may also be considered when selecting the data segment 23, for example by selecting the data segment 23 so that it covers an appropriate fraction of the total time needed for the recharging event. Appropriate percentages of the total time or absolute times that may be covered by the data segment 23 are given above. In the example shown in FIG. 2, the data segment 23 may comprise 60 seconds. In the example shown in FIG. 3, the data segment 23 may comprise 1200 seconds. However, these values are purely exemplary and any other suitable durations of the data segments 23 may be chosen.

According to the present disclosure, the information contained in the data segment 23 of the respective charging profiles may be enough to accurately determine or estimate the capacity of the energy storage 15 showing the respective charging profile during a charging event. It may therefore not be necessary to use all the data of the whole charging profile as shown in FIGS. 2 and 3 for the determination of the estimated capacity. It may also not be necessary to even collect the complete charging profile data as shown in FIGS. 2 and 3, as long as the data pertaining to the data segment 23 is available. The method according to the present disclosure may therefore also be used when only partial charging profiles are available.

In FIG. 4, a flow diagram of the method 30 according to the present disclosure is shown. As indicated by the continuous line in contrast to the dashed boxes of the other steps, the method 30 may only comprise steps 37, 38, and 40, which pertain to collecting charging profile data, especially current or present charging profile data, for example pertaining to the latest charging event, selecting the data segment 23 of the charging profile as outlined above and calculating the current or present capacity of the energy storage 15 from the data segment 23. All of the other steps describe preliminary work or optional features that may or may not be part of the method 30.

To provide the underlying data to establish the correspondence between the capacity of the energy storage 15 and the charging profile data, the method 30 may comprise the preliminary step 31 of collecting energy storage capacity data and step 32 of collecting charging profile data, for example training charging profile data, from charging events of the energy storage 15. The energy storage capacity data collected in step 31 may, for example, be collected by conventional means, for example through intrusive measurements or testing. As outlined above, the information contained in the data segment 23 of the charging profile may be enough to accurately estimate the capacity of the energy storage 15. The charging profile may be a charging voltage profile 19 or a charging current profile 20. It may also be provided that both a charging voltage profile 19 and a charging current profile 20 are used to increase the accuracy of method 30 further. Then, in step 33, the respective data segment 23 may be selected in the charging profile, particularly the training charging profile. In step 34, a mathematical function may be fitted to the data in the data segment 23, for example by regression analysis. The data or information provided by the energy storage capacity data and the mathematical function or the data segment 23 may then be matched or merged by the number of usage sessions that have been provided to a user by a device using the energy storage 15 from which the respective data has been collected (see step 35).

The matched or merged data resulting from step 35 may provide a link between the actual capacity of the energy storage 15 represented by the energy storage capacity data and the data comprised in the data segment 23 represented by the mathematical function and/or its coefficients. In other words, the matched or merged data resulting from step 35 establishes how the mathematical function and/or its coefficients may look like for different capacities of the energy storage 15. From this data, therefore, a capacity estimation model may be established in step 36. The establishing of the model may comprise an iterative process in which a plurality of models may be established and tested. Only the best model or models may be kept or stored, while models with poor or average performance may be dismissed. The establishing of the model may also comprise machine learning or the use of an artificial intelligence engine. As soon as a suitable model is established at the end of step 36, the preliminary work for the method 30 may be complete. The model may therefore be integrated into one or more of the aerosol-generating device 2, the companion device 3 and the computing device 18. For example, the model may be integrated into the firmware of one or more of these devices.

While the charging profile data collected in step 32 may be used for training and testing purposes and ultimately to establish the model in step 36, the charging profile data collected in step 37 may be fed into the model to determine an estimated capacity of the energy storage 15. For the charging profile data collected in step 37, there may not be energy storage capacity data available so that the capacity of the energy storage 15 has to be estimated via the model. For this purpose, in step 38, the data segment 23 may be selected in the charging profile of the charging profile data collected in step 37.

In step 39, a mathematical function may be fitted to the data in the data segment 23 selected in step 38. The same mathematical function may be used as in step 34, although a different function may be used as well. The mathematical function fitted to the data segment 23 may then be used in step 40 to calculate the capacity of the energy storage 15, for example the estimated current or present capacity of the energy storage 15 based on the charging profile data collected in step 37.

Step 39 is shown in a dashed box, because there may be other ways of processing the data of data segment 23. For example, the data segment 23 does not have to be fitted by a mathematical function. Instead, for instance, a similarity measure may be employed to determine the capacity of the energy storage 15 from the correspondence of the data comprised in the data segment 23 and the energy storage capacity data. Such a different way of processing the data may also be used in establishing said correspondence in the previous steps 34, 35, and 36 of method 30. Therefore, as other possibilities are available to exploit the correspondence and the data as explained in the present disclosure, using a mathematical function fitted to the data segment 23 is only one exemplary embodiment.

One example of what the estimated capacity of the energy storage 15 may be used for is given in step 41, in which the user may be notified of the estimated capacity of the energy storage 15. For example, the aerosol-generating device 2, the companion device 3 or the computing device 18 may display a message or other information informing the user of the estimated capacity. The user may also be notified of the state of health (SOH) of the energy storage 15, which may be defined as the current capacity divided by the maximum or original or nominal capacity of the energy storage 15. The estimated capacity of the energy storage 15 may also be used to judge whether or not the energy storage 15 has to be replaced, for example because the remaining capacity of the energy storage 15 is not enough to provide a predetermined number of consecutive usage sessions to the user without having to charge the device in between. This predetermined number may be, for example, one, two, three, four, five or more than five consecutive usage sessions. The information about the estimated capacity of the energy storage 15 may not have to be displayed for the user on the same device that it has been determined. For example, determining the estimated capacity may be performed on one of the devices of the aerosol-generating system 1 according to FIG. 1, while notifying the user of the estimated capacity according to step 41 may be performed by one of the other devices of the aerosol-generating system 1. Every possible combination may be considered. For this reason, the aerosol-generating device 2, the companion device 3 and/or the computing device 18 may comprise an output device or display device 25 (see FIG. 1). The output device or display device 25 may be configured to output or display the message or other information to the user, for example visually and/or acoustically. For instance, the output device or display device 25 may be a display, a loudspeaker, a touchscreen or something similar.

Steps 37, 38, and 39 may be performed every time that the energy storage 15 is recharged. The resulting data may be stored, for example in data storage 11. In this way, data pertaining to the evolution in time of the charging profile data may be collected. This may also be established, for example, through the fitted mathematical function or other means. For example, the evolution in time of the coefficients of the fitted mathematical function may be analysed. The collection of multiple instances of charging profile data may therefore be used, for example in step 42, to estimate the future capacity of the energy storage 15. The future capacity of the energy storage 15 may be extrapolated from the evolution in time of the charging profile data or the coefficients of the fitted mathematical function. In analogy to step 41, in step 43, the user may be notified of the future capacity or of the future state of health of the energy storage 15. The above explanations with regard to step 41 may therefore also apply to step 43. Apart from the future capacity or state of health of the energy storage 15, the user may also be notified about a point of time in the future when the capacity of the energy storage 15 falls below the capacity needed to provide the predetermined number of consecutive usage sessions to the user. The user may therefore be notified about a point in time in the future at which he should consider replacing energy storage 15.

Apart from notifying the user; the estimated capacity and/or the estimated future capacity of the energy storage 15 may also be transferred to a server device, for example a web server, of the manufacturer of the aerosol-generating system 1. The data received by the server device may be used in data analysis to improve product quality. The data may also be used in remote maintenance of the aerosol-generating device 2 or the companion device 3.

All in all, the present disclosure therefore provides an improved energy management or energy storage management aerosol-generating devices 2 and/or companion devices 3 configured to charge aerosol-generating devices 2 with energy.

For the purpose of the present description and of the appended claims, except where otherwise indicated, all numbers expressing amounts, quantities, percentages, and so forth, are to be understood as being modified in all instances by the term “about”. Also, all ranges include the maximum and minimum points disclosed and include any intermediate ranges therein, which may or may not be specifically enumerated herein. In this context, therefore, a number A is understood as A±10% of A. Within this context, a number A may be considered to include numerical values that are within general standard error for the measurement of the property that the number A modifies. The number A, in some instances as used in the appended claims, may deviate by the percentages enumerated above provided that the amount by which A deviates does not materially affect the basic and novel characteristic(s) of the claimed invention. Also, all ranges include the maximum and minimum points disclosed and include any intermediate ranges therein, which may or may not be specifically enumerated herein.

1-15. (canceled)

16. A computer-implemented method for estimating a capacity of an energy storage of an aerosol-generating device or a companion device configured to charge an aerosol-generating device with electrical energy, the method comprising:
collecting charging profile data of the energy storage, the charging profile data including a charging profile;
selecting, in the charging profile data, a data segment of the charging profile, wherein the data segment of the charging profile is selected so that the data segment lies next to a corner point of the charging profile; and
determining an estimated capacity of the energy storage from the data segment of the charging profile.

17. The method according to claim 16, wherein the charging profile is at least one of a charging voltage profile or a charging current profile of the energy storage.

18. The method according to claim 16, wherein the charging profile data is collected unintrusively at a device level.

19. The method according to claim 16, wherein the data segment of the charging profile is selected so that the data segment lies:
before a constant voltage (CV) point of the charging profile, or
after a constant current (CC) point of the charging profile.

20. The method according to claim 16, wherein the data segment of the charging profile is selected so that the data segment lies:
directly before a constant voltage (CV) point of the charging profile, or
directly after a constant current (CC) point of the charging profile.

21. The method according to claim 16, wherein the data segment of the charging profile is selected so that the data segment includes at most 30% or at most 25% or at most 20% or at most 15% or at most 10% or at most 5% of a time period of a time duration of the total charging profile.

22. The method according to claim 16, wherein the data segment of the charging profile is selected so that the data segment includes the total time period of the charging profile.

23. The method according to claim 16, further comprising:
fitting the data segment of the charging profile to a mathematical function; and
determining the capacity of the energy storage from the mathematical function.

24. The method according to claim 16, further comprising determining an estimated capacity of the energy storage from the data segment of the charging profile and a number of usage sessions provided to a user.

25. The method according to claim 16, further comprising:
collecting training charging profile data of the energy storage, the training charging profile data including a training charging profile;
selecting, in the training charging profile data, a data segment of the training charging profile;
collecting energy storage capacity data; and
correlating the data segment of the training charging profile with the energy storage capacity data.

26. The method according to claim 25, further comprising matching the data segment of the training charging profile with the energy storage capacity data by the number of usage sessions provided to a user by the aerosol-generating device or the companion device.

27. The method according to claim 25, further comprising establishing a capacity estimation model from a correlation of the data segment of the training charging profile and the energy storage capacity data.

28. The method according to claim 16, further comprising collecting and storing charging profile data of the energy storage each time the aerosol-generating device or the companion device is charged.

29. The method according to claim 28, further comprising selecting, from the plurality of stored charging profile data, a data segment of each charging profile, and predicting, from the plurality of data segments of the charging profiles, a capacity of the energy storage at a point of time in a future.

30. The method according to claim 16, further comprising calculating and displaying to a user and/or storing at least one of:
a current state of health of the energy storage from a current capacity of the energy storage,
a future state of health of the energy storage from a predicted capacity of the energy storage,
a point of time or a date in a future at which the capacity and/or the state of health of the energy storage will fall under a predetermined threshold with a predetermined degree of certainty,
whether or not the energy storage needs to be replaced, and/or
a point of time or a date in a future at which the energy storage will need to be replaced with a predetermined degree of certainty.

31. The method according to claim 16, further comprising sending the estimated capacity of the energy storage to a server device for data analysis and/or remote maintenance.

32. An aerosol-generating system, comprising at least one of an aerosol-generating device, a companion device configured to charge an aerosol-generating device with electrical energy, and a computing device, wherein the at least one of the aerosol-generating device, the companion device, and the computing device includes a processing circuitry including at least one processor, and wherein the processing circuitry is configured to perform steps of the method according to claim 16.

33. The aerosol-generating system according to claim 32, wherein the aerosol-generating device comprises an aerosol-generating substrate or an aerosol-generating article.

34. A nontransitory computer-readable medium having stored thereon computer-executable program code that, when executed on a computing device, causes the computing device to perform steps of the method according to claim 16.
